(19) United States
(12) Patent Application Publication
(10) Pub. No.: US 2017/0133525 A1
(43) Pub. Date: May 11, 2017

(54) INFRARED ABSORPTION BY CRYSTALLINE SILICON, COMPOSITIONS AND METHODS THEREOF

(71) Applicant: University of Massachusetts, Boston, MA (US)

(72) Inventors: Mengyan Shen, Belmont, MA (US); Qinghua Zhu, Lowell, MA (US)

(21) Appl. No.: 15/347,549

(22) Filed: Nov. 9, 2016

Related U.S. Application Data
(60) Provisional application No. 62/253,091, filed on Nov. 9, 2015.

(51) Int. Cl. H01L 31/0236; H01L 31/18; C30B 29/06; H01L 31/028

(52) U.S. Cl. CPC H01L 31/02363; H01L 31/028; H01L 31/1804; H01L 31/186; C30B 29/06

(57) ABSTRACT

The invention provides a novel method for fabrication of IR-absorbing silicon substrate in ambient atmosphere without the need for special background gases, and compositions and methods of preparation and use thereof.

### PRIORITY CLAIMS AND RELATED PATENT APPLICATIONS

This application claims the benefit of priority from U.S. Provisional Application Ser. No. 62/253,091, filed on Nov. 9, 2015, the entire content of which is incorporated herein by reference in its entirety.

### STATEMENT OF FEDERALLY SPONSORED RESEARCH

The United States Government has certain rights to the invention pursuant to Grant No. CMMI-1031111 awarded by National Science Foundation.

### TECHNICAL FIELDS OF THE INVENTION

The invention generally relates to silicon and optoelectronic applications. More particularly, the invention relates to a novel method for fabrication of IR-absorbing silicon substrates in ambient atmosphere without the need for special background gases, and compositions and methods of preparation and use thereof.

### BACKGROUND OF THE INVENTION

Silicon is the foundation of an immense global industry that depends on various forms of semiconductors to electronic devices. The large band gap of silicon solid in the infrared region, however, severely limits silicon's application in optoelectronics. Photons with wavelength longer than 1.1 μm cannot be absorbed by a silicon solid because the photon energy is not large enough to excite an electron from the valence band of the silicon solid to the conduction band. (Sai, et al. Appl. Phys. Lett. (2011) 98, 113502; Carlson, et al. Appl. Phys. Lett. (1976) 28, 671; Carey, et al. Opt. Lett. (2005) 30, 14; Zhou, et al. Appl. Phys. Lett. (2009) 94, 1; Zogg, et al. Opt. Eng. (1995) 34, 1964; Zogg, et al. Opt. Eng. (1994) 33, 1440.)

Femtosecond laser irradiation-based method was developed to improve the optical properties of silicon. Infrared absorption of silicon was achieved by fabricating a silicon substrate surface with a femtosecond laser irradiation in the presence of the background gases of SF₆. With sulfur atoms doped into the silicon surface, the band gap of silicon was filled with the sulfur impurity energy states. As a result, the increment absorption for IR light with photon energy less than 1.1 eV can be obtained. (Carey, et al. Opt. Lett. (2005) 30, 14; Her, et al. Appl. Phys. Lett. (1998) 73, 1673; Pedraza, et al. Appl. Phys. Lett. (2000) 77, 3018; Shen, et al. Appl. Phys. Lett. (2004) 85, 5694; Shen, et al. Nano. Lett. (2008) 8, 2087.)

It is desirable to develop methodologies and materials that allow for directly fabrication of IR-absorbing silicon substrates in ambient atmosphere without the need for special background gases.

### SUMMARY OF THE INVENTION

The invention is based, in part, on the unexpected discovery of a novel method for achieving infrared absorption of silicon via fabricating a silicon substrate surface with a femtosecond laser irradiation in air without the presence of any special background gases.

In one aspect, the invention generally relates to a crystalline silicon material exhibiting a nanostructured surface comprising amorphous and nanocrystalline regions, wherein the crystalline silicon material is characterized by a near-infrared absorption in the region from about 50 nm to about 3,000 nm that is at least 20% greater than the intrinsic absorption of a crystalline silicon.

In another aspect, the invention generally relates to a method for forming a nanostructured surface on a crystalline silicon material, comprising irradiating the surface of the crystalline silicon material with a femtosecond laser beam, in the absence of background gas or dopant, at an intensity and for a duration sufficient to form a nanostructured surface.

In yet another aspect, the invention generally relates to an electric device, or a component thereof, comprising a crystalline silicon material disclosed herein.

In yet another aspect, the invention generally relates to an electric device, or a component thereof, prepared by a method disclosed herein.

### BRIEF DESCRIPTION OF THE DRAWINGS

FIG. 1. The Raman spectrum of silicon after the irradiation of laser with pulse duration of 35 fs, an average laser fluence of 6 kJ/m² and a pulse number of 250. (a) The comparison of the Raman spectrum of the sample (the upper spectrum) with that of crystalline silicon that shows a clean peak at 520 cm⁻¹ (in the lower spectrum); (b) The deconvolution of the Raman spectrum between 100 cm⁻¹ and 600 cm⁻¹.

FIG. 2. SEM images of the Si surface after irradiation of laser with pulse duration of 35 fs, an average laser fluence of 6 kJ/m² and a pulse number of 250. (a) Si micro-hills; (b) Si micro-hills in (a) after rotating of about 90°; (c) structures on the top surface of silicon micro-hills in (b) for higher magnification; (d) structures on the side surface of silicon micro-hills in (b) for higher magnification; (e) magnified image of (c); (f) magnified image of (d).

FIG. 3. The optical absorption comparison of the femtosecond laser irradiated sample A with crystalline silicon. The silicon substrate has been irradiated with laser with pulse duration of 35 fs, an average laser fluence of 6 kJ/m² and a pulse number of 250.

FIG. 4. The optical absorptance of silicon after laser irradiation at two different laser pulse durations, 35 fs and 100 fs. The average laser fluence and pulse number are 6 kJ/m² and 250, respectively.

FIG. 5. Pulse number dependence of optical absorptance of silicon after laser irradiation. The pulse duration and the average laser fluence are 35 fs and 6 kJ/m², respectively.

FIG. 6. Laser fluence dependence of optical absorptance of silicon after laser irradiation. The pulse duration and the pulse number are 35 fs and 250, respectively.

FIG. 7. The radiation effect on the silicon. Sample A is made with the irradiation of the laser 35 fs pulse duration, fluence of 6 kJ/m² and 250 laser pulses; Sample B at 35 fs pulse duration, fluence of 7 kJ/m² and 250 laser pulses; and sample C at 35 fs pulse duration, fluence of 6 kJ/m² and 300 laser pulses. (a) The optical absorptance of silicon after different laser irradiations. (b) The Raman spectra of silicon samples after different laser irradiations.

### DETAILED DESCRIPTION OF THE INVENTION

The invention provides a novel method for achieving infrared absorption of silicon via fabricating a silicon substrate surface with a femtosecond laser irradiation in air without the presence of any special background gases. The unconventional methodology disclosed herein leads to the formation of nanocrystalline and amorphous composite microstructures on the silicon substrate surface, as evidenced by Raman spectroscopy. The composite microstructures lead to optical absorption enhancement both at the visible region and NIR region. For example, in the NIR region of 850 nm to 2,000 nm, the optical absorption can be boosted by 50% or more. Instead of doping silicon with sulfur impurities, this method of the invention achieves augmentation of IR absorption by generating amorphous and nano-structured silicon on substrate surface.

Because the avoidance of background sulfur gases such as SF₆, the present invention enables fabrication without the need for complex equipment and expansive facilities. In addition, comparing to the tradition amorphous silicon membrane that is coated on the silicon substrate surface, the amorphous and nano-structures are directly formed in the silicon surface, the silicon substrate of the present invention opens the material to novel applications that require firmly embedded IR-absorbing layers.

Furthermore, the absorption profile in the NIR range can be fine-tuned by adjusting femtosecond laser pulse energy, pulse number and pulse duration.

Silicon substrates fabricated by the present invention may be utilized in a variety of applications, for example, in infrared sensors, solar cells, gas sensors or analyzers, flame sensors, spectral analysis devices, and contact-free temperature thermometers. An NIR detector may be built, for example, for gas sensing using silicon material's large surface area.

Phonon Raman spectroscopy analysis of the fabricated surface showed that amorphous silicon as well as silicon nano-crystalline were generated on the silicon surface. Scanning electron microscope (SEM) images showed arrays of silicon hills in micrometers with smaller nano-scaled structures on the hills' surfaces. Before and after comparisons demonstrated that the infrared optical absorption was due to the femtosecond laser irradiation. This absorption was also found to be dependent on laser-processing parameters such as laser pulse duration, pulse number and pulse energy. The rise of the IR absorption was shown to originate from the composite of nano-crystalline silicon and amorphous silicon on the silicon substrate surface because amorphous silicon provides electronic energy states in the energy band gap for the IR absorption.

Thus, by way of the disclosed method, the smooth surface of silicon solid can be readily transformed into a composite of nanocrystalline silicon and amorphous silicon with microstructures using a simple femtosecond laser irradiation in air. The resulting microstructures were substantially across the silicon surfaces and are large enough to considerably influence the IR optical absorption of the fabricated silicon substrates.

In one aspect, the invention generally relates to a crystalline silicon material exhibiting a nanostructured surface comprising amorphous and nanocrystalline regions, wherein the crystalline silicon material is characterized by a near-infrared absorption in the region from about 50 nm to about 3,000 nm that is at least 20% greater than the intrinsic absorption of a crystalline silicon.

In certain embodiments, the crystalline silicon material is characterized by a near-infrared absorption in the region from about 1,100 nm to about 3,000 nm (e.g., from about 1,100 nm to about 2,500 nm, from about 1,100 nm to about 2,000 nm) that is at least 30% greater than the intrinsic absorption of a crystalline silicon.

In certain embodiments, the crystalline silicon material is characterized by a near-infrared absorption in the region from about 1,100 nm to about 1,700 nm (e.g., from about 1,100 nm to about 1,500 nm, from about 1,200 nm to about 1,600 nm) that is at least 50% (e.g., at least 60%, at least 70%, at least 80%) greater than the intrinsic absorption of a crystalline silicon.

The nanostructured surface may exhibit a number of nano-structured features. In certain embodiments, the surface of the crystalline silicon material exhibits a plurality of silicon micro-hills with triangular crosssections. In certain embodiments, the silicon micro-hills with triangular crosssections have bottom dimensions from about 0.03 mm to about 0.2 mm (e.g., from about 0.03 mm to about 0.15 mm, from about 0.03 mm to about 0.1 mm, from about 0.05 mm to about 0.2 mm, from about 0.1 mm to about 0.2 mm) and height dimensions from about 0.1 mm to about 0.4 mm (e.g., from about 0.1 mm to about 0.3 mm, from about 0.1 mm to about 0.2 mm, from about 0.2 mm to about 0.4 mm, from about 0.3 mm to about 0.4 mm). In certain embodiments, the silicon micro-hills are disposed in a side-by-side pattern.

In certain preferred embodiments, the nanostructured surface is induced by a femtosecond laser irradiation in the absence of any background gas providing one or more doping elements. In certain preferred embodiments, the nanostructured surface is substantially free of any doping elements. In certain preferred embodiments, the crystalline silicon material is substantially free of any doping elements.

In another aspect, the invention generally relates to a method for forming a nanostructured surface on a crystalline silicon material, comprising irradiating the surface of the crystalline silicon material with a femtosecond laser beam, in the absence of background gas or dopant, at an intensity and for a duration sufficient to form a nanostructured surface.

The femtosecond laser beam can be selected to produce the desired outcome in terms of the optical absorption. In certain embodiments, the femtosecond laser beam is characterized by having a pulse duration from about 35 fs to about 300 fs (e.g., from about 35 fs to about 200 fs, about 35 fs to about 150 fs, about 35 fs to about 100 fs, about 50 fs to about 300 fs, about 100 fs to about 300 fs, about 150 fs to about 300 fs); a pulse energy from about 0.5 mJ to about 10 mJ (e.g., from about 0.5 mJ to about 5.0 mJ, about 0.5 mJ to about 3 mJ, about 0.5 mJ to about 1.0 mJ, about 1.0 mJ to about 10 mJ, about 2.0 mJ to about 10 mJ, about 5.0 mJ to about 10 mJ); laser wavelength from about 1.5 μm to about 400 nm (e.g., from about 1.2 μm to about 400 nm, about 1.0 μm to about 400 nm), and a repetition rate from about 100 Hz to about 10 kHz (e.g., from about 100 Hz to about 1 kHz, about 100 Hz to about 500 Hz, about 500 Hz to about 10 kHz, about 1 kHz to about 10 kHz, about 5 kHz to about 10 kHz).

In certain embodiments, the femtosecond laser beam is characterized by a pulse duration of 35 fs, a pulse energy of 6 mJ pulses at a wavelength of 800 nm and from an amplified pulsed Ti:sapphire laser system.

In certain embodiments, the femtosecond laser beam is produced by the second harmonic generation at a wavelength of 400 nm and the third harmonic generation at a wavelength of 266.7 nm from an amplified pulsed Ti:sapphire laser system. In certain embodiments, the femtosecond laser beam can also be produced by other femtosecond laser systems providing laser beams with wavelengths from about 1200 nm to about 260 nm.

Any suitable temperature may be chosen as the condition of fabrication. For example, the irradiation can be carried out at an ambient temperature, under an ambient atmosphere, or both.

In certain embodiments, the method further includes cleaning the irradiated crystalline silicon material to remove any silicon dust. The cleaning step, for example, may be carried out with distilled water. In another embodiment, the cleaning step may be carried out with solutions, for example, with methanol, ethanol and acetone.

In certain embodiments, the method further includes removing a silicon oxide layer on the surface of the irradiated crystalline silicon material. The step of removing a silicon oxide layer, for example, may be carried out with hydrofluoric acid solution.

In yet another aspect, the invention generally relates to an electric device, or a component thereof, comprising a crystalline silicon material disclosed herein. In certain embodiments, the electric device or component thereof is selected from IR sensors, photovoteic cells with improved IR efficiency, gas sensors or analyzers, flame sensors, spectral analysis devices, and contact-free temperature thermometers.

In yet another aspect, the invention generally relates to an electric device, or a component thereof, prepared by a method disclosed herein.

### Examples

A clean silicon wafer (p-Si (100), thickness of 500 μm, resistivity of 20 Ω·m) was placed on the translation stage and was irradiated in air by a 1 kHz train of 35 fs, 6 mJ pulses at 800 nm wavelength from an amplified Ti: sapphire laser system with the incident laser beam perpendicular to the wafer surface. The sample was scanned line by line with the distance of 150 μm between two lines at even speed to make the silicon receive uniform exposure to the laser in an area of 1 cm×1 cm. Laser beam splitters are used to control the average laser fluence. The pulse duration was controlled by adjusting the laser compressor and measured by an autocorrelator around the sample surface location between a lens and its focal point. The sample translation velocity in the direction perpendicular to the laser beam direction was used to control the average pulse number irradiated on the substrate surface. The average pulse number n was calculated by applying the formula, n=wf/v, where w is the full width at half maximum (FWHM) of the Gaussian laser beam profile on the sample surface, f is the frequency of the laser pulse train, and v is the sample translation velocity. (Crouch, et al. Appl. Phys. A (2004) 79, 1635.) In this work, w was 100 μm, f was 1000, and v varied from 0.3 mm/s to 2.5 mm/s. After the laser irradiation, the silicon wafer was cleaned by distilled water ultrasonically to remove the silicon dust sprayed out during the laser treatment procedure and then further washed with 10% hydrofluoric acid to remove the silicon oxide layer formed during the laser ablation procedure. The cleaning procedure can eliminate the effect of silicon dust and silicon oxide layer during Raman spectrum test and optical absorptance measurement.

The crystallinity of the sample at room temperature was analyzed with a Raman spectrometer (Optic Senterra, Bruker). A continuous wave laser at the wavelength of 532 nm was used as the excitation source for the Raman spectroscopy measurement. The sample surface structure was also studied by using a scanning electron microscope (SEM, JEOL 7401F). The optical property of the sample was studied with a spectrophotometer (U-4001, HITACHI) equipped with a precise integrating sphere. The reflectance (R) and transmittance (T) were measured with the integrating sphere. The absorptance (A) of the sample was then obtained with the formula A=1−T−R.

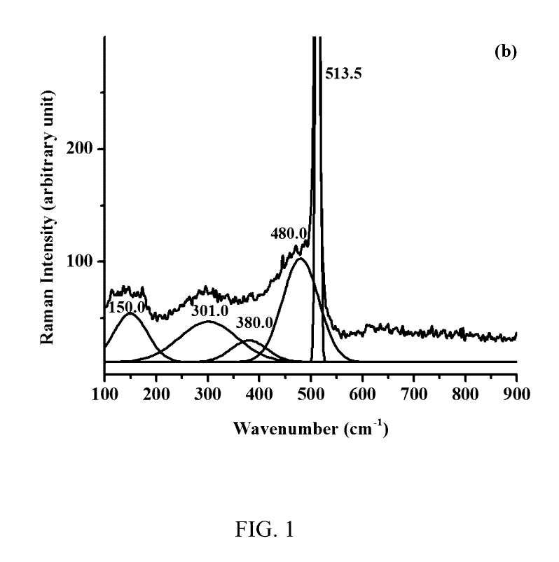

FIG. 1 shows the Raman spectrum of the c-Si after the femtosecond laser irradiation. Raman spectroscopy analysis is an effective method to study the silicon surface irradiated by femtosecond laser. In one experiment, the laser pulse duration was 35 fs, the average laser fluence was 6 kJ/m² and the pulse number was 250. FIG. 1a shows the comparison of Raman spectrum of laser processed Si with that of Si crystal. The Raman main peak of silicon crystal was at 520.0 cm⁻¹, while the main peak of the laser irradiated silicon shifted to lower energy from 520.0 cm⁻¹ to 513.5 cm⁻¹ with an asymmetry broadening. Because of the phonon confinement effect, the red shift and the asymmetric broadening of the one phonon Raman signal at 520 cm⁻¹ have been used to estimate the average size of small silicon crystals. The red shift and the asymmetry broadening of the Raman peak around 520.0 cm⁻¹ indicate that silicon nanocrystals were generated during the laser irradiation.

The Raman spectrum indicated that the average size of the generated silicon nanocrystals was around 10 nm although the spectrum cannot give the shapes and the size distribution of the silicon nanocrystals. FIG. 1b is the Raman spectrum of weak signals from wavenumber of 100 cm⁻¹ to 900 cm⁻¹. The broad shoulder near the nanocrystal Si peak of 513.5 cm⁻¹ can be observed. As shown in FIG. 1b, the spectrum was deconvoluted to obtain the peak centered at a wavenumber of 513.5 cm⁻¹ which belongs to the nanocrystal Si, and four broad peaks which are the characteristic peaks of amorphous silicon at wavenumber of 480 cm⁻¹ (TO mode), 380 cm⁻¹ (LO mode), 301 cm⁻¹ (LA mode), and 150 cm⁻¹ (TA mode). The Raman spectrum analysis revealed that nanostructured silicon and amorphous silicon were generated simultaneously during the laser irradiation. (Voutsas, et al. J. Appl. Phys. (1995) 78, 6999; Li, et al. Phys. Rev. B (1999) 59, 3; Iqbal, et al. J. Solid State Phys. (1982) 15, 377; Wu, et al. Appl. Phys. Lett. (1996) 69, 523; Saleh, et al. Thin Solid Films (2003) 427, 266; Wang, et al. Opt. Express (2010) 18, 18.)

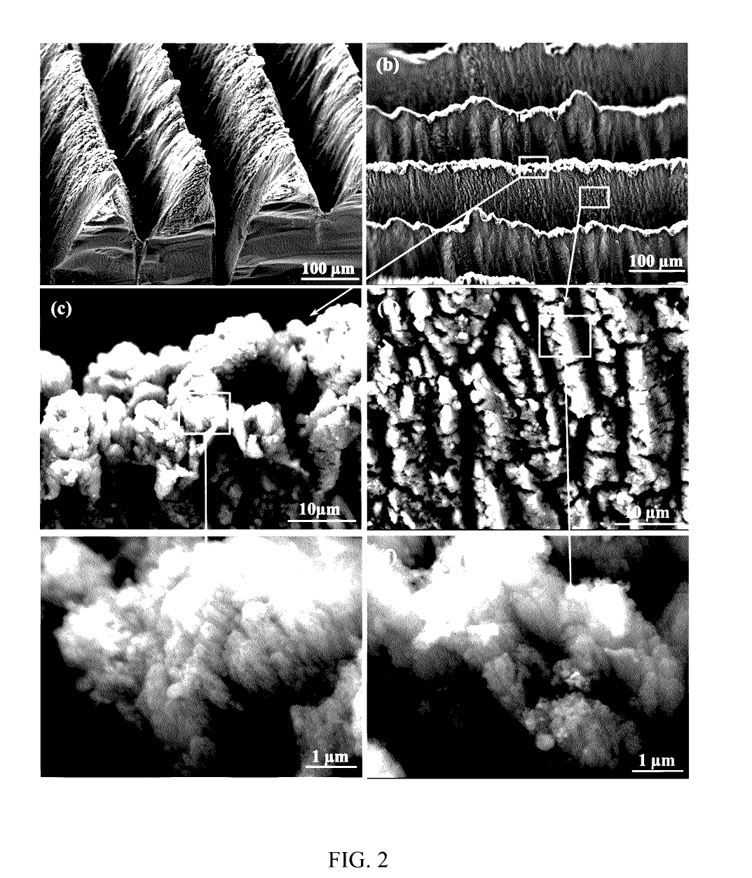

FIG. 2 shows the Si surface SEM images of the nano-structures formed on the silicon surface after the femtosecond laser irradiation that included arrays of silicon micro-hills. The micro-hills were formed because of the line-by-line laser scanning. The cross section of each one of the hills was in isosceles triangle-like shape. The bottom side of the triangle was about 80-micrometer long. The height of the triangle was about 100 micrometers. FIG. 2b shows the silicon micro-hill feature viewed after rotating the substrate at 90° and titling at 45° to the surface normal. FIGS. 2c and 2d show that on the surface of silicon micro-hills, there were smaller structures generated during the laser irradiation process. FIGS. 2e and 2f show the SEM image with larger magnification at different location of the hills; the images show the same nano- or submicro-structures at different locations of the surface of the micro-hill surfaces. The laser wavelength was 532 nm for the excitation source for the Raman spectroscopy measurement. The laser penetration depth, λ/4πκ, where λ and κ were the wavelength and the imaginary part of the complex refractive index of silicon, respectively, is less than 2 μm that is much smaller than the surface structures shown in the images of FIGS. 2e and 2f. The Raman signals of the sample were from the nanocrystals and amorphous silicon but not from the silicon crystal microstructures beneath the nanocrystals and amorphous silicon. Therefore, the crystal silicon was transformed into a composite of nanocrystalline, amorphous, and crystal silicon substrate surface with micro-morphologies.

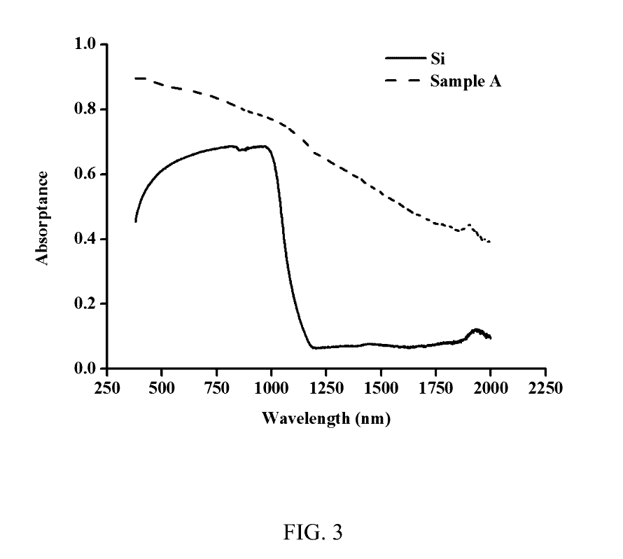

FIG. 3 shows the optical absorptance of a laser irradiated silicon sample between 380 nm to 2,000 nm. The experimental condition used was 35 fs pulse duration, 6 kJ/m² average pulse fluence and 250 laser pulses. The absorptance of regular silicon is also shown in FIG. 3 for the comparison with the laser irradiated Si sample. The absorptance of the sample almost linearly increased from 2,000 nm to 400 nm. The comparison indicates that the structured silicon's optical absorptance was much higher than that of the regular silicon in the measured wavelength range. The absorptance at wavelength of 1.5 μm of the structured silicon was about 50% higher than that of unstructured silicon substrate. In visible wavelengths part, the absorptance increment was mainly originated from the effect of multiple reflections, i.e., the incident light was reflected multiple times on the micro/nanostructured surface and was absorbed by the silicon. In near infrared region, there was an obvious drop in wavelength around 1.1 μm for the unstructured silicon absorptance curve, which was corresponding to the silicon band gap. The light with wavelength longer than 1.1 μm did not have enough photon energy to excite electron from the valence band to the conduction band of silicon solid. As a result, silicon was almost transparent to the light in this range. However, the silicon after laser irradiation had a large IR optical absorptance because the disordered amorphous silicon does not have a defined band gap.

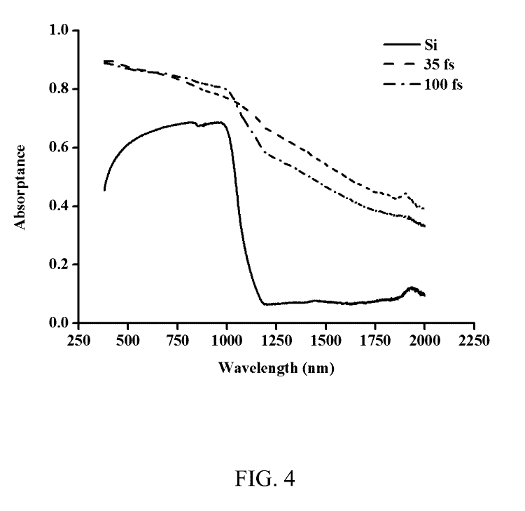

FIG. 4 shows laser pulse duration effect on the infrared absorptance when keeping the pulse number at 250 and the average pulse fluence at 6 kJ/m². As the pulse duration decreased from 100 to 35 fs, the infrared absorptance increased in the near-infrared range although changing the pulse duration did not make a large difference. The infrared absorptance change was less than 0.1 or 10%. Meanwhile, the disappeared band gap when the pulse duration was 35 fs around 1.1 μm was observable when the pulse duration was adjusted to 100 fs. When irradiating with longer pulse duration, less amorphous silicon was formed and less infrared absorptance was achieved.

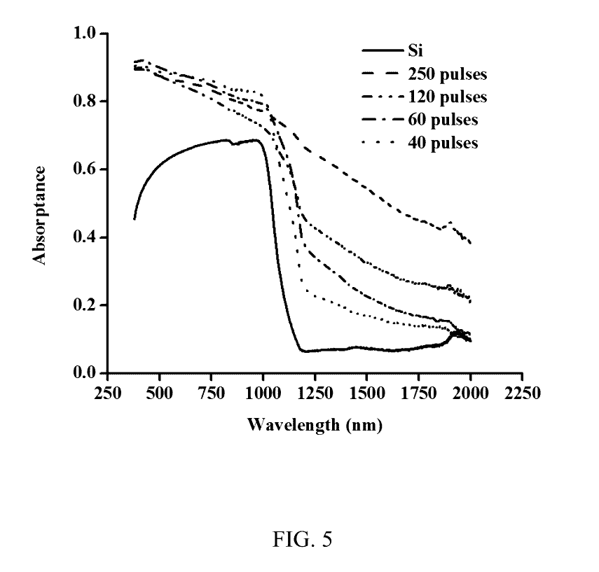

FIG. 5 shows the laser pulse number dependence of the optical absorptance while keeping the average laser fluence at 6 kJ/m² and the pulse duration at 35 fs. When the pulse number increased from 40 to 250, the absorptance changed less than 10% for the wavelength less than 1,000 nm, but increased significantly between 1,000 nm and 2,000 nm. For the small pulse number, the optical absorptance approached to that of unstructured silicon, i.e., although a small number of femtosecond pulse irradiation changed the surface structures, there was not enough amorphous silicon to change in the NIR optical property of the silicon substrate as a whole system. When the pulse number was 250, NIR absorptance reached the maximum. As the pulse number was larger than 250, the induced NIR absorptance became smaller.

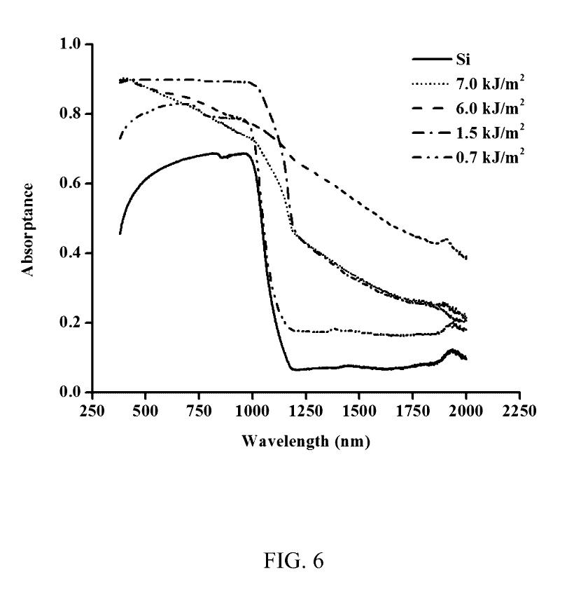

FIG. 6 shows the laser fluence dependence of optical absorptance when keeping the pulse number as 250 laser pulses and the pulse duration as 35 fs. For the wavelength between 1,250 nm and 2,000 nm, the absorptance increased as the laser fluence increased. For the case of average laser fluence of 1.5 and 0.7 kJ/m², the characteristic Si band gap could still be observed around wavelength of 1.1 μm. While as the fluence increase to 6 kJ/m², the band gap could not be found on the absorptance spectrum. However, it was also found that when the fluence became stronger than 6 kJ/m², the NIR absorptance became smaller and similar to that of Si irradiated with lower laser fluences as shown in FIG. 6 for the fluence of 7 kJ/m². This was opposite to the fluence dependence of optical absorptance when the fluence was weaker than 6 kJ/m².

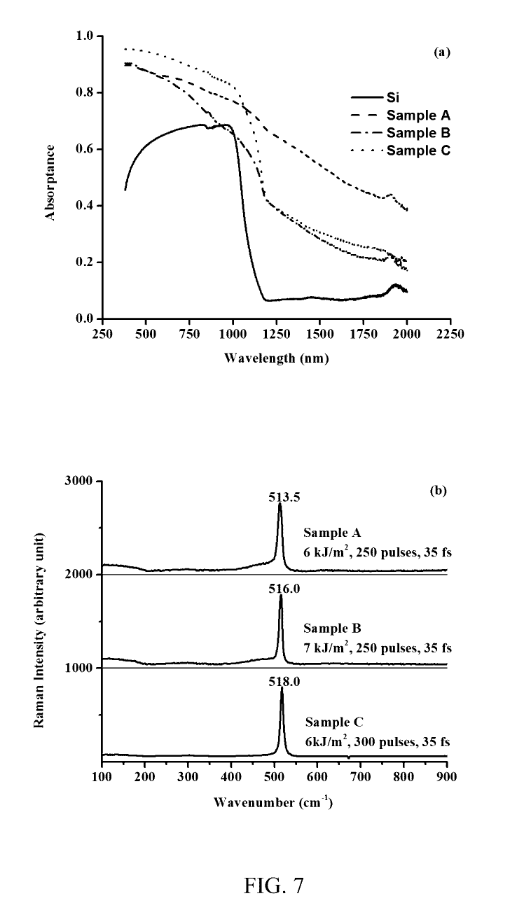

In FIG. 7a, Sample A in FIGS. 1 and 3 was compared with the samples with more irradiation, i.e. more accumulated irradiation energy absorbed by the substrate. Sample B was made with the irradiation of the laser 35 fs pulse duration, fluence of 7 kJ/m² and 250 laser pulses; and Sample C at 35 fs pulse duration, fluence of 6 kJ/m² and 300 laser pulses. FIG. 7b shows the corresponding Raman spectra of samples A, B and C. From the Raman spectra, which show the crystalline peak position of Sample A at 513.5 cm⁻¹, Sample B at 516.0 cm⁻¹, and Sample C at 518.0 cm⁻¹, respectively. The amorphous broad band at 480 cm⁻¹ in Samples B and C became weak relative to the crystalline peak in comparison with that in Sample A. Thus, the amorphous silicon became crystalline silicon when more laser energy was irradiated on the amorphous silicon, and the IR absorptance decreased as shown in FIG. 7a. Therefore, as the pulse number or pulse energy increased, the NIR absorptance decreased after reaching a maximum value. The silicon amorphous structures were back to silicon crystalline structures under the influence of laser irradiation. Therefore, the silicon structure can be changed back and forth between crystalline and amorphous by controlling the experimental conditions.

The Raman spectrum of the silicon after the laser irradiation shows that the crystalline silicon can change to amorphous silicon under the effect of laser irradiation. The obvious IR absorption indicated that there was a significant amount of amorphous silicon formed. The sharp and red shifted main Raman peak indicated that some of silicon in the surface was in the form of nanocrystalline.

Applicant's disclosure is described herein in preferred embodiments with reference to the Figures, in which like numbers represent the same or similar elements. Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

The described features, structures, or characteristics of Applicant's disclosure may be combined in any suitable manner in one or more embodiments. In the following description, numerous specific details are recited to provide a thorough understanding of embodiments of the invention. One skilled in the relevant art will recognize, however, that Applicant's composition and/or method may be practiced without one or more of the specific details, or with other methods, components, materials, and so forth. In other instances, well-known structures, materials, or operations are not shown or described in detail to avoid obscuring aspects of the disclosure.

In this specification and the appended claims, the singular forms “a,” “an,” and “the” include plural reference, unless the context clearly dictates otherwise.

Unless defined otherwise, all technical and scientific terms used herein have the same meaning as commonly understood by one of ordinary skill in the art. Although any methods and materials similar or equivalent to those described herein can also be used in the practice or testing of the present disclosure, the preferred methods and materials are now described. Methods recited herein may be carried out in any order that is logically possible, in addition to a particular order disclosed.

### INCORPORATION BY REFERENCE

References and citations to other documents, such as patents, patent applications, patent publications, journals, books, papers, web contents, have been made in this disclosure. All such documents are hereby incorporated herein by reference in their entirety for all purposes. Any material, or portion thereof, that is said to be incorporated by reference herein, but which conflicts with existing definitions, statements, or other disclosure material explicitly set forth herein is only incorporated to the extent that no conflict arises between that incorporated material and the present disclosure material. In the event of a conflict, the conflict is to be resolved in favor of the present disclosure as the preferred disclosure.

### EQUIVALENTS

The representative examples are intended to help illustrate the invention, and are not intended to, nor should they be construed to, limit the scope of the invention. Indeed, various modifications of the invention and many further embodiments thereof, in addition to those shown and described herein, will become apparent to those skilled in the art from the full contents of this document, including the examples and the references to the scientific and patent literature included herein. The examples contain important additional information, exemplification and guidance that can be adapted to the practice of this invention in its various embodiments and equivalents thereof.

1. A crystalline silicon material exhibiting a nanostructured surface comprising amorphous and nanocrystalline regions, wherein the crystalline silicon material is characterized by a near-infrared absorption in the region from about 50 nm to about 3,000 nm that is at least 20% greater than the intrinsic absorption of a crystalline silicon.

2. The crystalline silicon material of claim 1, wherein the crystalline silicon material is characterized by a near-infrared absorption in the region from about 1100 nm to about 3,000 nm that is at least 30% greater than the intrinsic absorption of a crystalline silicon.

3. The crystalline silicon material of claim 2, wherein the crystalline silicon material is characterized by a near-infrared absorption in the region from about 1,100 nm to about 1,700 nm that is at least 50% greater than the intrinsic absorption of a crystalline silicon.

4. The crystalline silicon material of claim 1, wherein the nanostructured surface comprises a plurality of silicon micro-hills with triangular crosssections.

5. The crystalline silicon material of claim 1, wherein the silicon micro-hills with triangular crosssections have bottom dimensions from about 0.03 mm to about 0.2 mm and height dimensions from about 0.1 mm to about 0.4 mm.

6. The crystalline silicon material of claim 1, wherein the silicon micro-hills are disposed in a side-by-side pattern.

7. The crystalline silicon material of claim 1, wherein the nanostructured surface is induced by a femtosecond laser irradiation in the absence of any background gas providing one or more doping elements.

8. The crystalline silicon material of claim 1, wherein the nanostructured surface is substantially free of doping elements.

9. The crystalline silicon material of claim 1, wherein the crystalline silicon material is substantially free of doping elements.

10. A method for forming a nanostructured surface on a crystalline silicon material, comprising irradiating the surface of the crystalline silicon material with a femtosecond laser beam, in the absence of background gas or dopant, at an intensity and for a duration sufficient to form a nanostructured surface.

11. The method of claim 10, wherein the femtosecond laser beam is characterized by:
pulse duration: from about 35 fs to about 300 fs;
pulse energy: from about 0.5 mJ to about 10 mJ;
laser wavelength: from about 1.5 micrometer to about 400 nm, and
repetition: from about 100 Hz to about 10 kHz.

12. The method of claim 11, wherein the femtosecond laser beam is 35 fs, 6 mJ pulses at 800 nm wavelength from an amplified pulsed Ti:sapphire laser system.

13. The method of claim 1, wherein the irradiation is carried out at an ambient temperature.

14. The method of claim 1, wherein the irradiation is carried out under an ambient atmosphere.

15. The method of claim 10, further comprising cleaning the irradiated crystalline silicon material to remove any silicon dust.

16. The method of claim 1, wherein the cleaning step is carried out with distilled water.

17. The method of claim 10, further comprising removing a silicon oxide layer on the surface of the irradiated crystalline silicon material.

18. The method of claim 17, wherein the step of removing a silicon oxide layer is carried out with hydrofluoric acid solution.

19. An electric device, or a component thereof, comprising a crystalline silicon material of claim 1.

20. An electric device, or a component thereof, prepared by a method according to claim 10.
